(19) United States
(12) Patent Application Publication
(10) Pub. No.: US 2011/0220204 A1
(43) Pub. Date: Sep. 15, 2011

(54) Method of Forming Light Absorption Layer and Solar Cell Structure Using the Same

(75) Inventors: Yueh-Chun Liao, Hsinchu City (TW); Mei-Wen Huang, Tainan City (TW); Yen-Chih Chen, Changhua City (TW)

(73) Assignee: INDUSTRIAL TECHNOLOGY RESEARCH INSTITUTE, Hsinchu (TW)

(21) Appl. No.: 12/980,610

(22) Filed: Dec. 29, 2010

(30) Foreign Application Priority Data
Mar. 11, 2010 (TW) 99107168

(51) Int. Cl. H01L 31/0256; H01L 31/18

(52) U.S. Cl. 136/262; 438/95; 257/E31.027

(57) ABSTRACT

A method for forming a light absorption layer including the following steps is provided. A controlling precursor is wet coated on a base precursor. The band gap of the controlling precursor is larger than that of the base precursor. The controlling precursor is a Group I-III-VI compound, and the Group I-III-VI compound is composed of Cuₐ(In_{1-b-c}Ga_{b}Al_{c})(Se_{1-d}S_{d})₂, wherein 0<a, 0≦b≦1, 0≦c≦1, 0<b+c≦1, and 0≦d≦1. Then, a heating process is performed so as to make the base precursor and the controlling precursor form the light absorption layer.

This application claims the benefit of Taiwan application Serial No. 099107168, filed Mar. 11, 2010, the subject matter of which is incorporated herein by reference.

### BACKGROUND

1. Technical Field

The disclosure relates in general to a method for forming a light absorption layer and a solar cell structure using the same, and more particularly to a method for forming a light absorption layer using two layers of precursors and a solar cell structure using the same.

2. Description of the Related Art

A solar cell converts the solar light into power. In general, the manufacturing process of a light absorption layer of the solar cell is one of the core technologies. The chemical composition and distribution of the light absorption layer influence the size of the band gap, so that the photoelectric conversion efficiency of the solar cell is further affected.

Previously, the light absorption layer is formed by the vacuum process such as co-evaporation, metal organic chemical vapor deposition (MOCVD) or sputtering with high-temperature calcination. However, the vacuum process and high-temperature calcination involve high manufacturing cost and complicated manufacturing process.

In addition, after the calcination process, elements with smaller band gaps are normally distributed at the top surface of the light absorption layer, and elements with larger band gaps are normally distributed at the bottom surface of the light absorption layer, so that the distribution of the composition at the top surface of the light absorption layer is inconsistent with that at the bottom surface of the light absorption layer. Thus, the open circuit voltage (Voc) of the solar cell having the light absorption layer may be lower than 0.4V. That is, the solar cell has low photoelectric conversion efficiency. As a result, how to provide a method for manufacturing a light absorption layer capable of saving cost and increasing the photoelectric conversion efficiency for the solar cell has become an imminent task for the industries.

### SUMMARY

The disclosure is directed to a method for forming a light absorption layer and a solar cell structure using the same. A controlling precursor is wet coated on a base precursor, and a heating process is performed so as to form the light absorption layer. Thus, the composition of the light absorption layer formed according to the disclosure can be uniformly distributed, so as to increase the photoelectric conversion efficiency of the solar cell structure using the light absorption layer.

According to a first aspect of the present disclosure, a method for forming a light absorption layer including the following steps is provided. A controlling precursor is wet coated on a base precursor. The band gap of the controlling precursor is larger than that of the base precursor. The controlling precursor is a Group I-III-VI compound, and the Group I-III-VI compound is composed of Cuₐ(In_{1-b-c}Ga_{b}Al_{c})(Se_{1-d}S_{d})₂, wherein 0<a, 0≦b≦1, 0≦c≦1, 0<b+c≦1, and 0≦d≦1. Then, a heating process is performed so as to make the base precursor and the controlling precursor form the light absorption layer.

According to a second aspect of the present disclosure, a solar cell structure is provided. The solar cell structure includes a substrate, a metal layer, a light absorption layer, a buffer layer, a window layer, a conductive layer and a plurality of conducting wires. The metal layer is disposed on the substrate. The light absorption layer is disposed on the metal layer. The light absorption layer is formed according to the following steps. A controlling precursor is wet coated on a base precursor, wherein the band gap of the controlling precursor is larger than that of the base precursor, the controlling precursor is a Group I-III-VI compound, and the Group I-III-VI compound is composed of Cuₐ(In_{1-b-c}Ga_{b}Al_{c})(Se_{1-d}S_{d})₂, 0<a, 0 b 1, 0 c 1, 0<b+c 1, and 0 d 1. A heating process is performed so as to make the base precursor and the controlling precursor form the light absorption layer. The buffer layer is disposed on the light absorption layer. The window layer is disposed on the buffer layer. The conductive layer is disposed on the window layer. The conducting wires are disposed on the conductive layer.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a solar cell structure according to a preferred embodiment of the disclosure;

FIG. 2 shows a flowchart of a method for forming a light absorption layer according to a preferred embodiment of the disclosure; and

FIG. 3 shows an XRD diagram of the light absorption layer formed without being coated with CuGaSe₂ and the light absorption layer coated with CuGaSe₂.

### DETAILED DESCRIPTION

A method for forming a light absorption layer and a solar cell structure using the same are disclosed in a number of embodiments below with accompanying drawings. However, a person having ordinary skill in the art should understand that these drawings and disclosures are for explanation purpose, not for limiting the scope of protection of the disclosure.

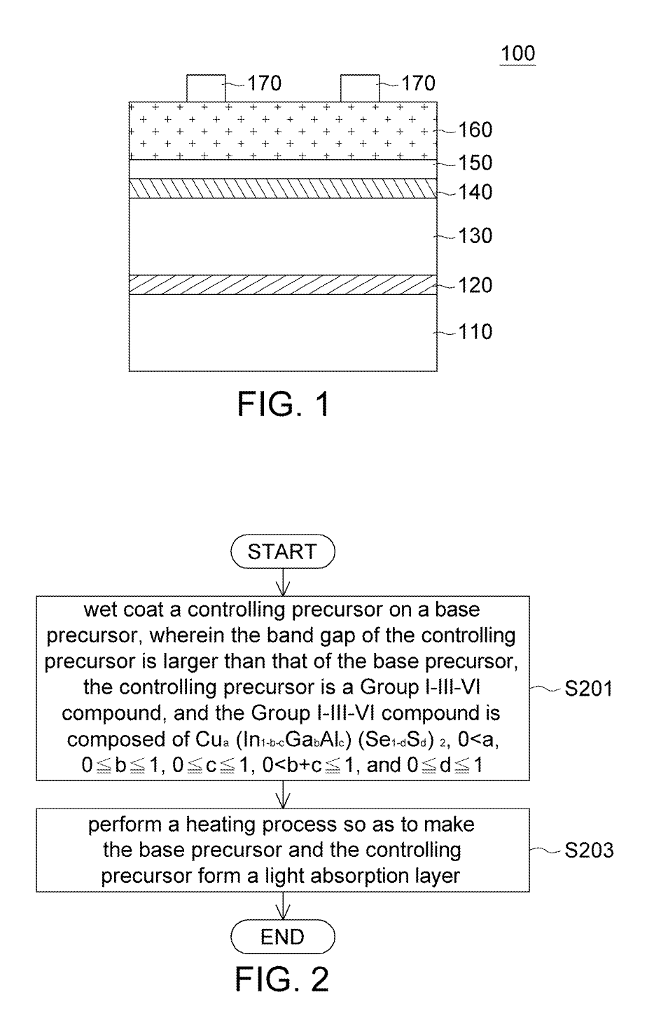

Referring to FIG. 1, a solar cell structure according to a preferred embodiment of the disclosure is shown. The solar cell structure 100 includes a substrate 110, a metal layer 120, a light absorption layer 130, a buffer layer 140, a window layer 150, a conductive layer 160 and several conducting wires 170. The disposition of each layer is disclosed below. The metal layer 120 is disposed on the substrate 110. The light absorption layer 130 is disposed on the metal layer 120. The buffer layer 140 is disposed on the light absorption layer 130. The window layer 150 is disposed on the buffer layer 140. The conductive layer 160 is disposed on the window layer 150. The conducting wires 170 are disposed on the conductive layer 160.

Referring to FIG. 2, a flowchart of a method for forming a light absorption layer according to a preferred embodiment of the disclosure is shown. In the present embodiment of the disclosure, the light absorption layer 130 is formed by the manufacturing method in FIG. 2, for example.

In the step S201, a controlling precursor is wet coated on a base precursor, wherein the controlling precursor can be a nanometer scale plasma and be coated on the base precursor by way of scraping, spraying or printing. In the present embodiment of the disclosure, the base precursor can be Group I-III-VI selenide, and the Group I-III-VI selenide refers to a Group I-III-VI compound with selenium. Or, the base precursor can be metal, alloy, oxide, hydroxide, sulfide or selenide containing copper, indium, aluminum or gallium. In addition, the controlling precursor is a Group I-III-VI compound, and the Group I-III-VI compound is composed of Cuₐ(In_{1-b-c}Ga_{b}Al_{c})(Se_{1-d}S_{d})₂, 0<a, 0≦b≦1, 0≦c≦1, 0<b+c≦1, and 0≦d≦1. Here, the Group I-III-VI compound refers to a combination of a Group 1B compound, a Group 3A compound and Group 6A compound. The Group 1B compound can be a compound with copper(Cu), gold(Au) or silver(Ag), the Group 3A compound can be a compound with boron(B), aluminum(Al), gallium(Ga), indium(In) or thallium(Tl), and the Group 6A compound can be a compound with oxygen(O), sulfur(S), selenium(Se), tellurium(Te) or polonium(Po). In addition, the thickness of the controlling precursor ranges between 1-3000 nanometers (nm), and the particle size of the controlling precursor is larger than or equal to 1 nm, for example. In the present embodiment of the disclosure, the controlling precursor is a compound containing sulfur, selenium, or the combination of sulfur and selenium, and the band gap of the controlling precursor is preferably larger than that of the base precursor.

Next, in the step S203, a heating process is performed so as to sinter the base precursor and the controlling precursor to form the light absorption layer 130. Here, the heating process can be performed at the temperature ranging between 300-700° C. for calcination or selenization, or the heating process can be performed with adding other gas at the temperature ranging between 300-700° C.

Thus, the composition of the light absorption layer 130 formed according to the above steps is uniformly distributed, so that the size of the band gap of the light absorption layer 130 can be effectively controlled. Furthermore, the top surface of the light absorption layer 130 has high Ga/In ratio, so that a diffraction angle which corresponds to the maximum diffraction peak of crystal face [112]/[103] of the light absorption layer 130 shifts towards a high angle to become greater than 26.7°. Thus, the open circuit voltage of the solar cell structure 100 having the light absorption layer 130 can be larger than 0.4V.

In the method for manufacturing the light absorption layer of the present embodiment of the disclosure, the base precursor is realized by Cu(In_{0.7}Ga_{0.3})Se₂, and the controlling precursor is realized by CuGaSe₂ (that is, in the Group compound Cuₐ(In_{1-b-c}Ga_{b}Al_{c})(Se_{1-d}S_{d})₂, a=1, b=1, c=0, and d=0).

Firstly, a metal layer which is made of molybdenum is sputtered on the substrate.

Next, a Cu(In_{0.7}Ga_{0.3})Se₂ nanometer scale plasma with 10% of solid content is scraped to form a 2.5 μm thick Cu(In_{0.7}Ga_{0.3})Se₂ dry film on the metal layer.

Then, a CuGaSe₂ nanometer scale plasma with 4% of solid content is scraped to form a 150 nm thick CuGaSe₂ dry film on the Cu(In_{0.7}Ga_{0.3})Se₂ dry film.

After that, the Cu(In_{0.7}Ga_{0.3})Se₂ dry film and the CuGaSe₂ dry film are calcined for 20 minutes at a temperature of 550° C. in an anaerobic environment with selenium vapor to form a light absorption layer.

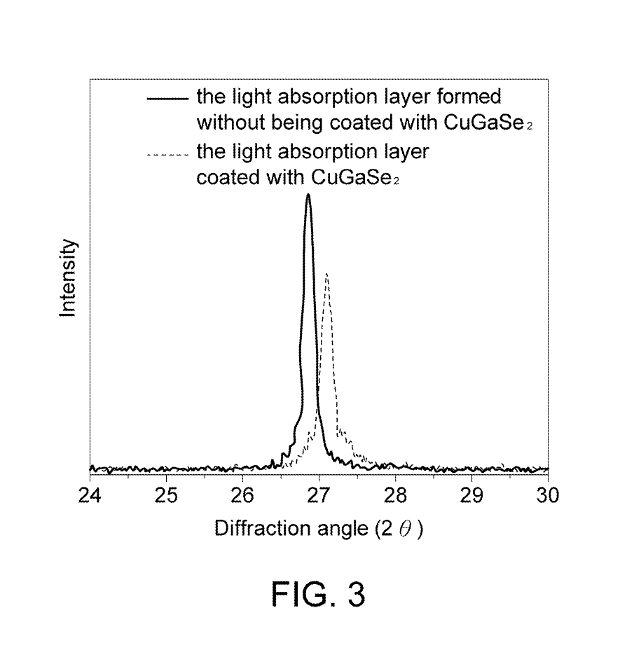

The properties of the light absorption layer formed without being coated with CuGaSe₂ (the controlling precursor) and the light absorption layer coated with CuGaSe₂ are analyzed and compared through an X-ray diffractometer (XRD). Referring to FIG. 3, an XRD diagram of the light absorption layer formed without being coated with CuGaSe2 and the light absorption layer coated with CuGaSe₂ is shown. As indicated in FIG. 3, a diffraction angle corresponding to the maximum diffraction peak of the crystal face [112]/[103] of the light absorption layer formed without being coated with CuGaSe₂ is about 26.85°, and a diffraction angle corresponding to the maximum diffraction peak of the crystal face [112]/[103] of the light absorption layer coated with CuGaSe₂ is about 27.07°. Therefore, the above results show that the light absorption layer coated with CuGaSe₂ has higher Ga/In ratio so that the diffraction angle corresponding to the maximum diffraction peak of the crystal face [112]/[103] of the light absorption layer shifts towards a high angle to become greater than 26.7°.

Then, the buffer layer, the window layer, the conductive layer and the conducting wires are sequentially formed on the light absorption layer so as to complete the manufacturing of the solar cell structure. Here, the buffer layer is cadmium sulfide, the window layer is zinc oxide, and the conductive layer is aluminum oxide (AZO), for example. The measurement of the solar cell structure shows that the open circuit voltage (Voc) of the solar cell structure having the light absorption layer coated with CuGaSe₂ is 0.53V. In comparison, the open circuit voltage of the solar cell structure having the light absorption layer without being coated with CuGaSe₂ is 0.39V. That is, according to the method for manufacturing a light absorption layer using two layers of precursors, the photoelectric conversion efficiency of the solar cell structure of the present embodiment of the disclosure is effectively increased.

In the method for manufacturing the light absorption layer of the another embodiment of the disclosure, the base precursor is realized by Cu(In_{0.7}Ga_{0.3})Se₂, and the controlling precursor is realized by Cu(In_{0.5}Ga_{0.5})Se₂ (that is, in the Group compound Cuₐ(In_{1-b-c}Ga_{b}Al_{c})(Se_{1-d}S_{d})₂, a=1, b=0.5, c=0, and d=0).

Firstly, a metal layer which is made of molybdenum is sputtered on the substrate.

Next, a Cu(In_{0.7}Ga_{0.3})Se₂ nanometer scale plasma with 10% of solid content is scraped to form a 2.5 μm thick Cu(In_{0.7}Ga_{0.3})Se₂ dry film on the metal layer.

Then, a Cu(In_{0.5}Ga_{0.5})Se₂ nanometer scale plasma with 5% of solid content is scraped to form a 150 nm thick Cu(In_{0.5}Ga_{0.5})Se₂ dry film on the Cu(In_{0.7}Ga_{0.3})Se₂ dry film.

After that, the Cu(In_{0.7}Ga_{0.3})Se₂ dry film and the Cu(In_{0.5}Ga_{0.5})Se₂ dry film are calcined for 20 minutes at a temperature of 550° C. in an anaerobic environment with selenium vapor to form a light absorption layer.

The measurement of the solar cell structure shows that the open circuit voltage (Voc) of the solar cell structure having the light absorption layer coated with Cu(In_{0.5}Ga_{0.5})Se₂ is 0.46V. In comparison, the open circuit voltage of the solar cell structure having the light absorption layer without being coated with Cu(In_{0.5}Ga_{0.5})Se₂ is 0.39V.

According to the method for forming a light absorption layer and a solar cell structure using the same disclosed in the above embodiments of the disclosure, the controlling precursor is wet coated on the base precursor, and the heating process is performed so as to form the light absorption layer. Thus, the composition of the light absorption layer of the present embodiment of the disclosure is uniformly distributed, so that the photoelectric conversion efficiency of the solar cell structure using the light absorption layer is effectively increased. Furthermore, since the controlling precursor of the present embodiment of the disclosure is a nanometer scale plasma, the thickness of the controlling precursor is very easy to control. Besides, the thermal stability of the compound precursor is higher than that of the metal precursor, so that the composition of the light absorption layer with the compound precursor formed after the heating process is easy to control. Moreover, the light absorption layer formed by the controlling precursor made of metal oxide tends to have the residue of metal oxide after a high-temperature heating process. In comparison, the light absorption layer of the present embodiment of the disclosure effectively avoids the residue of metal oxide.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for forming a light absorption layer, comprising:
wet coating a controlling precursor on a base precursor, wherein the band gap of the controlling precursor is larger than that of the base precursor, the controlling precursor is a Group I-III-VI compound, and the Group I-III-VI compound is composed of Cuₐ(In_{1-b-c}Ga_{b}Al_{c})(Se_{1-d}S_{d})₂, 0<a, 0 b 1, 0 c 1, 0<b+c 1, and 0 d 1; and
performing a heating process so as to make the base precursor and the controlling precursor form the light absorption layer.

2. The method for forming the light absorption layer according to claim 1, wherein the base precursor is a Group I-III-VI selenide.

3. The method for forming the light absorption layer according to claim 1, wherein the thickness of the controlling precursor ranges between 1-3000 nanometers (nm).

4. The method for forming the light absorption layer according to claim 1, wherein the particle size of the controlling precursor is larger than or equal to 1 nm.

5. The method for forming the light absorption layer according to claim 1, wherein the temperature of performing the heating process ranges between 300-700° C.

6. A solar cell structure, comprising:
a substrate;
a metal layer disposed on the substrate;
a light absorption layer disposed on the metal layer, wherein the light absorption layer is formed according to the following steps, comprising:
wet coating a controlling precursor on a base precursor, wherein the band gap of the controlling precursor is larger than that of the base precursor, the controlling precursor is a Group I-III-VI compound, and the Group I-III-VI compound is composed of Cuₐ(In_{1-b-c}Ga_{b}Al_{c})(Se_{1-d}S_{d})₂, 0<a, 0≦b≦1, 0≦c≦1, 0<b+c≦1, and 0≦d≦1; and
performing a heating process so as to make the base precursor and the controlling precursor form the light absorption layer;
a buffer layer disposed on the light absorption layer;
a window layer disposed on the buffer layer;
a conductive layer disposed on the window layer; and
a plurality of conducting wires disposed on the conductive layer.

7. The solar cell structure according to claim 6, wherein a diffraction angle corresponding to the maximum diffraction peak of the crystal face [112]/[103] of the light absorption layer is larger than 26.7°.

8. The solar cell structure according to claim 6, wherein the base precursor is a Group I-III-VI selenide.

9. The solar cell structure according to claim 6, wherein the thickness of the controlling precursor ranges between 1-3000 nanometers (nm).

10. The solar cell structure according to claim 6, wherein the particle size of the controlling precursor is larger than or equal to 1 nm.

11. The solar cell structure according to claim 6, wherein the temperature of performing the heating process ranges between 300-700° C.
